(19) United States
(12) Patent Application Publication
(10) Pub. No.: US 2026/0177935 A1
(43) Pub. Date: Jun. 25, 2026

(54) VIBRATION-CORRECTION UNIT, METHOD FOR OPERATING A VIBRATION-CORRECTION UNIT, SENSOR AND LITHOGRAPHY APPARATUS HAVING A SENSOR

(71) Applicant: Carl Zeiss SMT GmbH, Oberkochen (DE)

(72) Inventor: Rafael MARANGONI, Schwaebisch Gmuend (DE)

(21) Appl. No.: 19/542,184

(22) Filed: Feb. 17, 2026

Related U.S. Application Data
(63) Continuation of application No. PCT/EP2024/074518, filed on Sep. 3, 2024.

(30) Foreign Application Priority Data
Sep. 8, 2023 (DE) 10 2023 208 718.9

(51) Int. Cl. G03F 7/00

(52) U.S. Cl. CPC G03F 7/709; G03F 7/70833

(57) ABSTRACT

A vibration-correction unit is configured to be used in a lithography apparatus, such as a microlithographic projection exposure apparatus. A method is used to operate such a vibration-correction unit. A sensor is designed to be used in a lithography apparatus. A lithography apparatus, such as a projection exposure apparatus or an illumination apparatus, comprises such a sensor

### CROSS-REFERENCE TO RELATED APPLICATIONS

The present application is a continuation of, and claims benefit under 35 USC 120 to, international application No. PCT/EP 2024/074518, filed Sep. 3, 2024, which claims benefit under 35 USC 119 of German Application No. 10 2023 208 718.9, filed Sep. 8, 2023. The entire disclosure of each of these applications is incorporated by reference herein.

### FIELD

The disclosure relates to a vibration-correction unit for a lithography apparatus, such as a microlithographic projection exposure apparatus, and to a method for operating a vibration-correction unit. Furthermore, the disclosure relates to a sensor for a lithography apparatus and to a lithography apparatus, such as a projection exposure apparatus or an illumination apparatus, having a sensor.

### BACKGROUND

Projection exposure apparatuses are used to produce extremely fine structures, in particular on semiconductor components or other microstructured component parts. The operating principle of the apparatuses is based on the production of extremely fine structures down to the order of nanometers by way of generally reducing imaging of structures on a mask, a so-called reticle, on an element to be structured, a so-called wafer, that is provided with photosensitive material. The minimum dimensions of the structures produced are in general directly dependent on the wavelength of the light used. The light is usually shaped for the optimum illumination of the reticle in an illumination optics unit. Recently, light sources having an emission wavelength in the order of a few nanometers, for example between 1 nanometer (nm) and 120 nm, such as on the order of 13.5 nm, have increasingly been used. The described wavelength range is also referred to as the EUV range.

Apart from with the use of systems which operate in the EUV range, the microstructured component parts are also produced using commercially established DUV systems, which have a wavelength of between 100 nm and 300 nm, such as 193 nm. With the desire to be able to produce smaller and smaller structures, the desired optical correction properties in the systems have likewise increased further. Throughput is increased to increase economic efficiency with each new generation of projection exposure apparatuses in the EUV range or DUV range.

A plurality of sensors are used to increase image position accuracy and image quality. The sensors can detect the position of an object, or its velocity or else the acceleration acting on the object. These sensors are used for example in the illumination device and/or the projection lens of the microlithographic projection exposure apparatus, but can also be used in the measurement of optical elements for a lithography apparatus. Furthermore, in particular acceleration sensors or velocity sensors can be used to actively damp a vibration isolation system of a sensor frame having at least one position sensor. Alternatively or additionally, it is also possible to use acceleration sensors or velocity sensors in feedforward control for actively damping vibrations of optical elements and frames, such as sensor frames or force frames. The positioning of objects in the lithography apparatus, for example optical elements, can in turn be detected by position sensors. It is thus also possible to reduce line-of-sight errors and overlay errors in the imaging of the lithography apparatus via a plurality of differently designed sensors, i.e. acceleration sensors and/or velocity sensors and/or position sensors.

In order to make it possible to position and control the optical elements as accurately as reasonably possible, a carrying structure is present, on which position sensors are mounted. The position sensors are used to measure the position of the optical element relative to the carrying structure. The carrying structure is mechanically decoupled from the environment in order to increase the accuracy of the sensor system. The decoupling can be effected by a suspension with one or a plurality of springs or air springs, optionally on a further carrying structure or on a mounting. The movement effected by the carrying structures or an element of the lithography apparatus, i.e. the acceleration to be detected, are often very small. The use of conventional acceleration sensors is only possible to a very limited extent, since they can exhibit excessively high noise and thus a poor signal-to-noise ratio.

The German patent application filed under application number 10 2023 204 733.0 discloses an acceleration sensor formed as a displacement sensor and having an evaluation unit configured to convert the detected distance into an acceleration by differentiation twice.

### SUMMARY

The present disclosure seeks to provide an improved vibration-correction unit, an improved method for operating a vibration-correction unit, an improved sensor and an improved lithography apparatus having a sensor.

In an aspect, the disclosure provides a vibration-correction unit for an object in a lithography apparatus having a sensor connected to the object, the sensor comprising an electromagnetic actuator and an auxiliary mass, which is connected to at least one coil projecting into a cavity of the electromagnetic actuator and is designed for a linear movement along at least one measuring axis, wherein the electromagnetic actuator, for example its coil, is configured to generate a magnetic flux density in the region of the at least one coil, comprises a control unit configured to detect a measurement variable of the coil, and to convert into an acceleration acting on the auxiliary mass along the measuring axis, and a compensation unit configured to exert on the object a counterforce directed counter to the determined acceleration. This can help enable the force/acceleration acting on the auxiliary mass and thus on the object, i.e. vibrations acting on the object, to be detected with an improved signal-to-noise ratio and to be compensated for or at least reduced. The control unit and the correction unit can be combined into one component or can be different components.

For more accurately ascertaining the acceleration, the auxiliary mass can be connected to two spaced-apart coils projecting into the cavity of the electromagnetic actuator.

For generating the magnetic flux density in the region of the at least one coil of the electromagnetic actuator, it is desirable for the electromagnetic actuator to have at least one permanent magnet or at least one further actuator coil.

Furthermore, according to the disclosure provision is made for the auxiliary mass to be connected to the object directly or indirectly via a spring. The spring makes it possible to define a linear movement of the auxiliary mass and makes it possible for the movement of the auxiliary mass to be linear in response to the vibrations. This in turn makes it possible to increase the sensitivity of the sensor in the frequency range of between 1 Hz and 200 Hz. The auxiliary mass can be connected to the object directly, or else indirectly via a sensor housing, for example. Furthermore, the spring of the auxiliary mass can be selected such that the suspension frequency is between 0.1 Hz and 100 Hz, such as between 0.1 Hz and 50 Hz, for example between 1 Hz and 30 Hz. The spring can be formed as a leaf spring or as a helical spring. Alternatively or additionally, it is also possible for the spring to be formed as a permanent magnetic gravity compensator. Furthermore, more complex geometries can also be selected for the spring. For example, two magnetically identically oriented magnets can be arranged at a distance from one another along an axis which can be arranged parallel to the measuring axis. Provided in the central region of this axial magnetic arrangement is an outer circumferential magnetic ring, which at least partially encloses the inner magnets. The outer magnetic ring is magnetically oriented transversely with respect to the inner magnets, with the result that the inner pole of the outer magnet is adjacent to a like pole of the first inner magnet and to an opposite pole of the second inner magnet. This can result in a magnetic force along the longitudinal axis between the inner and outer magnets which remains almost constant despite a relative displacement of the outer magnet with respect to the inner magnets in a wide range of displacement. This magnetic force can be used as a compensation force and thus decouples the auxiliary mass from the object. Furthermore, it is also possible for the spring to be formed as a combination of a leaf spring or a helical spring with a permanent magnetic gravity compensator. Alternatively, the spring can also be formed as a plurality of helical springs and/or leaf springs that are coupled to one another. For example, it can be desirable for the spring to be formed as a gravity compensator in the direction of gravity.

Furthermore, the electromagnetic actuator can have a housing, which at least partially encloses the cavity and is formed from a ferromagnetic material. This can help enable the other elements of the sensor to be magnetically shielded vis-à-vis the magnetic field of the permanent magnet. The housing can have at least one opening through which the at least one coil projects into the cavity.

In the context of the disclosure, it is firstly desirable for the measurement variable of the coil to be a voltage induced in the at least one coil and the control unit is configured to determine a velocity of the auxiliary mass on the basis of the detected induced voltage and to convert the velocity into an acceleration via the first derivative. This enables an indirect measurement of the acceleration of the auxiliary mass and thus of the object by way of the voltage induced in the coil. According to Faraday's law, the voltage induced in the coil is proportional to the velocity and the magnetic flux density of the electromagnetic actuator. The movement of the auxiliary mass thus displaces the coil within the electromagnetic actuator, thereby changing the magnetic field and inducing a voltage in the at least one coil, which is in turn a measure of the velocity at which the auxiliary mass is moving. In contrast to an acceleration sensor based on a displacement sensor, in which the detected measurement variable is differentiated twice in order to determine the acceleration, differentiation can be done once in the case of the present sensor, which can help enable the object's current acceleration to be determined relatively quickly.

Alternatively, the measurement variable of the coil can be a current intensity or an electrical current intensity supplied to the at least one coil of the electromagnetic actuator. The acceleration acting on the auxiliary mass and thus on the object is in general proportional to the magnetic flux density, the length of the at least one coil and the supplied current intensity. In one embodiment, for detecting the electrical current intensity, an electrical resistor electrically connected to the coil and a detection unit are present.

Furthermore, it is desirable for a displacement sensor to be additionally present, which is configured to ascertain the position of the auxiliary mass. The auxiliary sensor can be connected to the object indirectly, for example via a housing, or directly.

Furthermore, a control structure can be present, wherein the control structure is configured to supply electrical current to the coil of the electromagnetic actuator in such a way that the position of the auxiliary mass detected by the displacement sensor is constant along the measuring axis. The control structure can keep the position of the auxiliary mass constant, for example stationary or at least stationary with respect to the at least one measuring axis. The current intensity supplied to the coil can thus be selected via the control structure in such a way that the position of the auxiliary mass detected by the displacement sensor is constant. The current intensity supplied to the at least one coil in the context of the control structure is in turn proportional to the acceleration acting on the object.

In this connection, it is desirable for the displacement sensor to be an optical displacement sensor, for example an optical encoder or an interferometer. The optical encoder can comprise a scale, a light source, and a grating. Optical encoders typically include a beam splitter that splits the light emitted by the light source into two beams. The two beams are incident on the diffraction grating at two different positions and are diffracted there. The first beam is then projected onto a first mirror via a λ/4 plate and the second beam is projected onto a second mirror via a further λ/4 plate, where they are each reflected back onto the diffraction grating, diffracted there and directed back onto the beam splitter. The interference pattern indicated on the scale changes as a result of the movement of the object and thus a change in distance between the object and the auxiliary mass. Alternatively, the displacement sensor can also be formed as a capacitive sensor.

Furthermore, the sensor can have a calibration unit for calibrating the sensor. In this case, it is desirable for the calibration unit to be formed as an electromagnetic element which has a calibration coil, which is connected to the auxiliary mass, and projects into a cavity of the electromagnetic element, and also has a displacement or velocity sensor for detecting the movement or velocity of the auxiliary mass. The electromagnetic element can be formed as a permanent magnet, but can also be formed as a coil. The calibration unit is configured to energize the calibration coil with at least two different predefined or predefinable current intensities, in such a way that the calibration coil causes a movement of the auxiliary mass. The calibration unit additionally can be configured to detect the movement of the auxiliary mass via the displacement sensor and to convert it into a velocity, or to detect the velocity of the auxiliary mass directly via the velocity sensor (e.g. a Doppler interferometer). Furthermore, the calibration unit is configured additionally to detect the voltage induced in the electromagnetic actuator by the movement of the auxiliary mass. A calibration value is thus formed as the value of the voltage induced in the coil of the electromagnetic actuator at a detected velocity. This calibration value, i.e. the induced voltage divided by the velocity, corresponds to the magnetic flux density multiplied by the length of the coil of the electromagnetic actuator. This calibration value or the calibration values can be stored in a memory. For a calibration, the induced voltage can be detected at at least two different velocities and stored in a memory. It goes without saying that the calibration can be carried out a number of times at predefined current intensities (velocities of the auxiliary mass). The voltmeter and/or the displacement sensor of the sensor can also be formed as the voltmeter and/or displacement sensor of the calibration unit, that is to say that the sensors used for vibration measurement can be also used for calibration. The calibration value or values detected in this way, i.e. the calibration unit, can be applied both to the measuring arrangement in which the measurement variable is the induced voltage and to the measuring arrangement in which the measurement variable is the supplied current intensity. Furthermore, it goes without saying that the detected or determined (converted) velocity can be converted into an acceleration via forming the first derivative.

Alternatively, it is desirable for the electromagnetic actuator itself to be part of the calibration unit. In this case, there is no additional electromagnetic element for calibration. The calibration unit thus comprises a voltmeter, a displacement or velocity sensor, a voltage source and a control and evaluation unit. The calibration unit is configured to energize the coil of the electromagnetic actuator with different current intensities, in such a way that a movement of the auxiliary mass is induced, and (at the same time) to determine the voltage induced in the electromagnetic actuator by the movement of the auxiliary mass via the voltmeter and the velocity detected via the displacement sensor or the velocity sensor. The calibration value or values detected in this way, i.e. the calibration unit, can be applied both to the measuring arrangement in which the measurement variable is the induced voltage and to the measuring arrangement in which the measurement variable is the supplied current intensity.

In a further alternative embodiment, in which the electromagnetic actuator itself is part of the calibration unit, the coil of the electromagnetic actuator is formed as a bifilar coil, in such a way that a first winding of the coil forms a measuring coil of the sensor for vibration measurement and a second winding of the coil forms the calibration coil. The calibration unit is in turn configured to energize the calibration coil (i.e. the second winding of the coil) with different current intensities, in such a way that a movement of the auxiliary mass is initiated, which is detected via the displacement sensor and is converted into a velocity or is detected directly via a velocity sensor. Moreover, the calibration unit is configured to detect the voltage induced in the measuring coil (i.e. the first winding of the coil) on account of the movement of the auxiliary mass via a voltmeter and to assign the detected or determined velocities to the values of the induced voltage as calibration values and to store them in a memory. The calibration value or values detected in this way, i.e. the calibration unit, can be applied both to the measuring arrangement in which the measurement variable is the induced voltage and to the measuring arrangement in which the measurement variable is the supplied current intensity.

In the context of the disclosure, it is desirable for the object to be formed as a sensor frame, wherein the sensor frame has at least one position sensor for an optical element. An optical element can be suspended from the sensor frame. The sensor frame can be decoupled from the environment via a vibration isolation system, in particular via a spring or an air spring. Since, despite the vibration isolation system, in particular at the resonant frequency of the vibration isolation system, vibration of the sensor frame may nevertheless occur, the acceleration of the sensor frame can be determined via the at least one sensor according to the disclosure comprising the electromagnetic actuator and a counterforce directed counter to the determined acceleration can be initiated via an actuator. The actuator can be the electromagnetic actuator of the sensor, or else a further actuator. Alternatively, the vibration isolation system can additionally have a viscous damper in order to damp unwanted vibrations of the vibration isolation system. The sensor frame can be suspended from a force frame. Alternatively or additionally, it is desirable for the object to be a force frame for an optical element of the lithography apparatus, in particular of the microlithographic projection exposure apparatus, wherein the force frame is connected to the optical element or a further optical element and at least one actuator connected to the optical element is mounted on the force frame for the purpose of adjusting or deforming the optical element.

Alternatively, the object can also be an optical element of the lithography apparatus, in particular of the microlithographic projection exposure apparatus, for example a mirror or a lens element.

In order to be able to ascertain the acceleration of the object along a plurality of measuring axes or also with respect to a rotation axis, it is desirable for at least one second sensor comprising an electromagnetic actuator and an auxiliary mass to be present, which is configured to detect the acceleration acting on the object along a second axis differing from the measuring axis. The axes can be linearly independent, in particular perpendicular. Alternatively, the first sensor and the second sensor can also be arranged parallel to one another at a distance L from one another. Besides a translational degree of freedom, this additionally makes it possible to ascertain the acceleration along a rotation axis. In order to be able to measure the movement of the object in all six rigid body degrees of freedom, it is in turn desirable for a total of six of the above-described sensors to be present, which are each configured to ascertain a measurement variable of the coil along mutually different measuring axes. In particular, for ascertaining the 6 rigid body degrees of freedom, 3 arrangements each having two sensors arranged parallel to one another at the distance L can be present, wherein the 3 arrangements are arranged linearly independently of one another, optionally perpendicularly, on the object. In this case, a spring suspension of the respective auxiliary masses can be dispensed with, since the auxiliary mass is kept suspended via the electromagnetic actuator.

Furthermore, it is desirable for a further acceleration sensor to be additionally present, which is formed in a manner free of an electromagnetic actuator, for determining the acceleration of the object along at least one axis. In this context, the acceleration sensor can be configured to determine the acceleration in a measurement frequency range differing from the measurement frequency range of the sensor having the electromagnetic actuator, or to detect the acceleration in a measurement frequency range of greater than 100 Hz. The at least one acceleration sensor can be formed as a piezoceramic sensor, but other types of acceleration sensors are also possible, in particular sensors also embodied as MEMS sensors (Micro-Electro-Mechanical Sensors), such as MOEMS sensors (Micro-Opto-Electro-Mechanical Sensors). In particular, it is desirable for at least one acceleration sensor to be respectively present for each of the six rigid body degrees of freedom of the object. The acceleration sensor can be likewise mounted on the object. The movement of the object can be detected both by the acceleration sensor and by the sensor comprising the electromagnetic actuator.

Since the signal-to-noise ratio for the sensor comprising the electromagnetic actuator below approximately 100 Hz is better than the signal-to-noise ratio of the further acceleration sensor and, conversely, the signal-to-noise ratio for the further acceleration sensor above approximately 100 Hz is better than for the sensor comprising the electromagnetic actuator, it is desirable for a low-pass filter to be present for the purpose of attenuating the detected signal from the sensor comprising the electromagnetic actuator above a predefined cutoff frequency or a cutoff frequency range, and a high-pass filter is assigned to the at least one further acceleration sensor for the purpose of attenuating the detected signal below a predefined cutoff frequency or a cutoff frequency range, and the sum of the transfer function of the signals from the further acceleration sensor and the sensor comprising the electromagnetic actuator is approximately 1. The cutoff frequency can be approximately in the range of 50 Hz to 500 Hz, such as between 70 Hz and 300 Hz, for example between 100 Hz and 200 Hz. In other words, optionally, the measurement data detected by the sensor comprising the electromagnetic actuator (distances or else distances differentiated once or twice) are used for smaller movements of the object, which (when Fourier-transformed) are smaller than a cutoff frequency or a cutoff frequency range, and the measurement data detected by the further acceleration sensor are used for larger movements of the object, which are greater than a cutoff frequency or a cutoff frequency range. The larger movements which are detected by the sensor comprising the electromagnetic actuator and are greater than the cutoff frequency or the cutoff frequency range are in turn damped via the low-pass filter and the smaller movements which are detected by the further acceleration sensor and are smaller than the cutoff frequency or the cutoff frequency range can be damped via the high-pass filter.

The method for operating a vibration-correction unit according to the disclosure comprises at least the following steps:
a. detecting a measurement variable of a coil via the sensor comprising the electromagnetic actuator and the auxiliary mass,
b. determining the acceleration acting on the object along a measuring axis on the basis of the detected measurement variable of the coil
c. generating a counterforce directed counter to the acceleration on the object in order to compensate for vibrations.

The features, embodiments and above-described configurations of the vibration-correction unit can be applied to the method for operating the vibration-correction unit.

In the context of the method, it is firstly especially desirable for the measurement variable of the coil to be a voltage induced in the at least one coil of the electromagnetic actuator. According to Faraday's law, the voltage induced in the at least one coil is proportional to the velocity and the magnetic flux density B. The movement of the auxiliary mass thus displaces the coil within the electromagnetic actuator, thereby changing the magnetic field and inducing a voltage in the at least one coil, which is in turn a measure of the velocity at which the auxiliary mass is moving.

In this connection, it is desirable for the acceleration to be determined by the voltage induced in the at least one coil being converted into a velocity and the velocity being differentiated once with respect to time. In comparison with the displacement sensor, in order to determine the acceleration acting on the object, differentiation can be done once, as a result of which it is possible to determine the acceleration more quickly.

Alternatively, the measurement variable of the coil can be an electrical current intensity supplied to the at least one coil of the electromagnetic actuator.

The acceleration can be determined by detecting that current intensity supplied to the at least one coil which is desirable to keep the position of the auxiliary mass constant, to keep the position constant at least along the measuring axis, optionally to keep it stationary.

In order also to be able to detect movements of the object above 100 Hz with a good signal-to-noise ratio over a wide frequency range, the detected signals—i.e. movements—which are greater than a predefined or predefinable cutoff frequency or a cutoff frequency range of the sensor comprising the electromagnetic actuator are attenuated via a low-pass filter, and if the detected signals—i.e. movements—which are smaller than a predefined or predefinable cutoff frequency or cutoff frequency range of the further acceleration sensor (for example a piezoceramic sensor) can be attenuated using a high-pass filter, wherein the sum of the transfer function of the signals from the sensor comprising the electromagnetic actuator and the further acceleration sensor is approximately 1. In other words, optionally, the signals detected by the sensor comprising the electromagnetic actuator are used for smaller movements of the object below the cutoff frequency or below the cutoff frequency range, and the measurement signals detected by the further acceleration sensor are used for larger movements of the object above the cutoff frequency and above the cutoff frequency range. The larger movements which are detected by the sensor comprising the electromagnetic actuator and are greater than the cutoff frequency or the cutoff frequency range are damped via the low-pass filter and the smaller movements which are detected by the further acceleration sensor and are smaller than the cutoff frequency or the cutoff frequency range can be damped via a high-pass filter.

The sensor according to the disclosure for a lithography apparatus for detecting a measurement variable of an object has an electromagnetic actuator and an auxiliary mass, wherein the auxiliary mass is connected to at least one coil projecting into a cavity of the electromagnetic actuator and is designed for a linear movement along at least one measuring axis. The electromagnetic actuator is configured to generate a magnetic flux density in the region of the at least one coil. Moreover, a control unit is present, which is configured to detect a measurement variable of the coil. This enables the measurement variable acting on the auxiliary mass and thus on the object to be detected. The sensor is connected or connectable to the object directly or indirectly. In one embodiment, the control unit can be configured to convert the detected measurement variable of the coil into an acceleration acting on the auxiliary mass along the measuring axis. This enables the acceleration or force acting on the auxiliary mass and thus on the object to be detected.

In particular, it is desirable for the sensor to be formed as a position sensor and if the control unit is configured to convert the detected measurement variable into a position of the object, in particular by integrating.

Alternatively or additionally, it is desirable for the sensor to be formed as a velocity sensor, and if the control unit is configured to convert the detected measurement variable into a velocity of the object.

For more accurately ascertaining the measurement variable of the object, i.e. an acceleration or a velocity or a position, the auxiliary mass can be connected to two spaced-apart coils projecting into the cavity of the electromagnetic actuator.

For generating the magnetic flux density in the region of the at least one coil of the electromagnetic actuator, it is desirable for the electromagnetic actuator to have at least one permanent magnet or at least one further actuator coil.

Furthermore, it is desirable for the auxiliary mass to be connected to the object directly or indirectly via a spring. The spring makes it possible to define a linear movement of the auxiliary mass and makes it possible for the movement of the auxiliary mass to be linear in response to the vibrations. This in turn makes it possible to increase the sensitivity of the sensor in the frequency range of between 1 Hz and 200 Hz. The auxiliary mass can be connected to the object directly, or else indirectly via a sensor housing, for example. Furthermore, the spring of the auxiliary mass can be selected such that the suspension frequency is between 0.1 Hz and 100 Hz, such as between 0.1 Hz and 50 Hz, for example between 1 Hz and 30 Hz. The spring can be formed as a leaf spring or as a helical spring. Alternatively or additionally, it is also possible for the spring to be formed as a permanent magnetic gravity compensator. Furthermore, more complex geometries can also be selected for the spring. For example, two magnetically identically oriented magnets can be arranged at a distance from one another along an axis which can be arranged parallel to the measuring axis. Provided in the central region of this axial magnetic arrangement is an outer circumferential magnetic ring, which at least partially encloses the inner magnets. The outer magnetic ring is magnetically oriented transversely with respect to the inner magnets, with the result that the inner pole of the outer magnet is adjacent to a like pole of the first inner magnet and to an opposite pole of the second inner magnet. This results in a magnetic force along the longitudinal axis between the inner and outer magnets which remains almost constant despite a relative displacement of the outer magnet with respect to the inner magnets in a wide range of displacement. This magnetic force can be used as a compensation force and thus decouples the auxiliary mass from the object. Furthermore, it is also possible for the spring to be formed as a combination of a leaf spring or a helical spring with a permanent magnetic gravity compensator. Alternatively, the spring can also be formed as a plurality of helical springs and/or leaf springs that are coupled to one another. In particular, it is desirable for the spring to be formed as a gravity compensator in the direction of gravity.

Furthermore, the electromagnetic actuator can have a housing, which at least partially encloses the cavity and is formed from a ferromagnetic material. This enables the other elements of the sensor to be magnetically shielded vis-à-vis the magnetic field of the permanent magnet. The housing can have at least one opening through which the at least one coil projects into the cavity.

In the context of the disclosure, it is firstly desirable for the measurement variable of the coil to be a voltage induced in the at least one coil and the control unit is configured to determine a velocity of the auxiliary mass on the basis of the detected induced voltage. According to Faraday's law, the voltage induced in the coil is proportional to the velocity and the magnetic flux density of the electromagnetic actuator. The movement of the auxiliary mass thus displaces the coil within the electromagnetic actuator, thereby changing the magnetic field and inducing a voltage in the at least one coil, which is in turn a measure of the velocity at which the auxiliary mass is moving. In contrast to an acceleration sensor based on a displacement sensor, in which the detected measurement variable is differentiated twice in order to determine the acceleration, differentiation can be done once in the case of the present sensor, which enables the object's current acceleration to be determined more quickly. If the sensor is formed as a velocity sensor, the determined velocity can be used. If the sensor is formed as an acceleration sensor, the detected velocities can be converted into an acceleration by forming the first derivative. This enables an indirect measurement of the acceleration of the auxiliary mass and thus of the object by way of the voltage induced in the coil. Alternatively, the determined acceleration can also be converted into a velocity again by integration. If the sensor is formed as a position sensor, either the determined accelerations can be integrated twice and thus converted into a position of the object, or the determined velocities of the object can be converted into a position by integrating.

Alternatively, the measurement variable of the coil can be a current intensity or an electrical current intensity supplied to the at least one coil of the electromagnetic actuator. The acceleration acting on the auxiliary mass and thus on the object is proportional to the magnetic flux density, the length of the at least one coil and the supplied current intensity. In one embodiment, for detecting the electrical current intensity, an electrical resistor electrically connected to the coil and a detection unit are present. If the sensor is formed as a velocity sensor, the control unit is configured to convert the determined acceleration into a velocity of the object by integrating. On the other hand, if the sensor is formed as a position sensor, the control unit is configured to convert the determined acceleration into the position of the object by integrating (integrating twice).

Furthermore, it is desirable for a displacement sensor to be additionally present, which is configured to ascertain the position of the auxiliary mass. The auxiliary sensor can be connected to the object indirectly, for example via a housing, or directly.

Furthermore, a control structure can be additionally present, wherein the control structure is configured to supply electrical current to the coil of the electromagnetic actuator in such a way that the position of the auxiliary mass detected by the displacement sensor is constant along the measuring axis. The control structure keeps the position of the auxiliary mass constant, in particular stationary or at least stationary with respect to the at least one measuring axis. The current intensity supplied to the coil is thus selected via the control structure in such a way that the position of the auxiliary mass detected by the displacement sensor is constant. The current intensity supplied to the at least one coil in the context of the control structure is in turn proportional to the acceleration acting on the object. If the sensor is formed as a velocity sensor, the control unit is configured to convert the determined acceleration into a velocity of the object by integrating. On the other hand, if the sensor is formed as a position sensor, the control unit is configured to convert the determined acceleration into the position of the object by integrating (integrating twice).

In this connection, it is desirable for the displacement sensor to be an optical displacement sensor, for example an optical encoder or an interferometer. The optical encoder can comprise a scale, a light source, and a grating. Optical encoders typically include a beam splitter that splits the light emitted by the light source into two beams. The two beams are incident on the diffraction grating at two different positions and are diffracted there. The first beam is then projected onto a first mirror via a λ/4 plate and the second beam is projected onto a second mirror via a further λ/4 plate, where they are each reflected back onto the diffraction grating, diffracted there and directed back onto the beam splitter. The interference pattern indicated on the scale changes as a result of the movement of the object and thus a change in distance between the object and the auxiliary mass. Alternatively, the displacement sensor can also be formed as a capacitive sensor.

In the context of the disclosure, it is desirable for the object to be formed as a sensor frame, wherein the sensor frame has at least one position sensor for an optical element. An optical element can be suspended from the sensor frame. The sensor frame can be decoupled from the environment via a vibration isolation system, in particular via a spring or an air spring. Since, despite the vibration isolation system, in particular at the resonant frequency of the vibration isolation system, vibration of the sensor frame may nevertheless occur, the acceleration of the sensor frame can be determined via the at least one sensor according to the disclosure comprising the electromagnetic actuator and a counterforce directed counter to the determined acceleration can be initiated via an actuator. The actuator can be the electromagnetic actuator of the sensor, or else a further actuator. Alternatively, the vibration isolation system can additionally have a viscous damper in order to damp unwanted vibrations of the vibration isolation system. The sensor frame can be suspended from a force frame. Alternatively or additionally, the object can be a force frame for an optical element of the lithography apparatus, in particular of the microlithographic projection exposure apparatus, wherein the force frame is connected to the optical element or a further optical element and at least one actuator connected to the optical element is mounted on the force frame for the purpose of adjusting or deforming the optical element.

Alternatively, the object can also be an optical element of the lithography apparatus, in particular of the microlithographic projection exposure apparatus, for example a mirror or a lens element.

In order to be able to ascertain the measurement variable of the object along a plurality of measuring axes or also with respect to a rotation axis, it is desirable for at least one second sensor comprising an electromagnetic actuator and an auxiliary mass to be present, which is configured to detect the acceleration acting on the object along a second axis differing from the measuring axis. The axes can be linearly independent, in particular perpendicular. Alternatively, the first sensor and the second sensor can also be arranged parallel to one another at a distance L from one another. Besides a translational degree of freedom, this additionally makes it possible to ascertain the measurement variable of the object along a rotation axis. In order to be able to measure the measurement variable, in particular the movement, of the object in all six rigid body degrees of freedom, it is in turn desirable for a total of six of the above-described sensors to be present, which are each configured to ascertain a measurement variable of the coil along mutually different measuring axes. In particular, for ascertaining the 6 rigid body degrees of freedom, 3 arrangements each having two sensors arranged parallel to one another at the distance L can be present, wherein the 3 arrangements are arranged linearly independently of one another, optionally perpendicularly, on the object. In this case, a spring suspension of the respective auxiliary masses can be dispensed with, since the auxiliary mass is kept suspended via the electromagnetic actuator.

Furthermore, it is desirable for a further acceleration and/or velocity and/or position sensor to be additionally present, which is formed in a manner free of an electromagnetic actuator, for determining the measurement variable of the object, i.e. an acceleration, velocity or position of the object along at least one axis. In this connection, the further acceleration and/or velocity and/or position sensor can be configured to determine the acceleration in a measurement frequency range differing from the measurement frequency range of the sensor having the electromagnetic actuator, or to detect the acceleration in a measurement frequency range of greater than 100 Hz. The at least one acceleration sensor can be formed as a piezoceramic sensor, but other types of acceleration sensors are also possible, in particular sensors also embodied as MEMS sensors (Micro-Electro-Mechanical Sensors), such as MOEMS sensors (Micro-Opto-Electro-Mechanical Sensors). In particular, it is desirable for at least one further acceleration and/or velocity and/or position sensor to be respectively present for each of the six rigid body degrees of freedom of the object. This further acceleration and/or velocity and/or position sensor can be likewise mounted on the object. The position or movement of the object can be detected both by the further acceleration and/or velocity and/or position sensor and by the sensor comprising the electromagnetic actuator.

Since the signal-to-noise ratio for the sensor comprising the electromagnetic actuator below approximately 100 Hz is better than the signal-to-noise ratio of the further acceleration and/or velocity and/or position sensor and, conversely, the signal-to-noise ratio for the further acceleration and/or velocity and/or position sensor above approximately 100 Hz is better than for the sensor comprising the electromagnetic actuator, it is desirable for a low-pass filter to be present for the purpose of attenuating the detected signal from the sensor comprising the electromagnetic actuator above a predefined cutoff frequency or a cutoff frequency range, and a high-pass filter is assigned to the at least one further acceleration and/or velocity and/or position sensor for the purpose of attenuating the detected signal below a predefined cutoff frequency or a cutoff frequency range, and the sum of the transfer function of the signals from the further acceleration and/or velocity and/or position sensor and the sensor comprising the electromagnetic actuator is approximately 1. The cutoff frequency can be approximately in the range of 50 Hz to 500 Hz, such as between 70 Hz and 300 Hz, for example between 100 Hz and 200 Hz. In other words, optionally, the measurement data detected by the sensor comprising the electromagnetic actuator (distances or else distances differentiated once or twice) are used for smaller movements of the object, which (when Fourier-transformed) are smaller than a cutoff frequency or a cutoff frequency range, and the measurement data detected by the further acceleration and/or velocity and/or position sensor are used for larger movements of the object, which are greater than a cutoff frequency or a cutoff frequency range. The larger movements which are detected by the sensor comprising the electromagnetic actuator and are greater than the cutoff frequency or the cutoff frequency range are in turn damped via the low-pass filter and the smaller movements which are detected by the further acceleration and/or velocity and/or position sensor and are smaller than the cutoff frequency or the cutoff frequency range can be damped via the high-pass filter.

A method for operating a sensor connected to an object can comprise at least the following steps:
a. detecting a measurement variable of the coil via the sensor comprising the electromagnetic actuator and the auxiliary mass, and
b. determining the acceleration acting on the object along a measuring axis on the basis of the detected measurement variable of the coil.

The features, embodiments and above-described configurations of the sensor can be applied to the method for operating the sensor.

In the context of the method, it is firstly especially desirable for the measurement variable of the coil to be a voltage induced in the at least one coil of the electromagnetic actuator. According to Faraday's law, the voltage induced in the at least one coil is proportional to the velocity and the magnetic flux density B. The movement of the auxiliary mass thus displaces the coil within the electromagnetic actuator, thereby changing the magnetic field and inducing a voltage in the at least one coil, which is in turn a measure of the velocity at which the auxiliary mass is moving.

In this connection, it is desirable for the acceleration to be determined by the voltage induced in the at least one coil being converted into a velocity and the velocity being differentiated once with respect to time. In comparison with the displacement sensor, in order to determine the acceleration acting on the object, differentiation can be done once, as a result of which it is possible to determine the acceleration more quickly. If the sensor is formed as a position sensor, it is desirable for the determined acceleration to be converted into a position of the object by integrating.

Alternatively, the measurement variable of the coil can be an electrical current intensity supplied to the at least one coil of the electromagnetic actuator. If the sensor is formed as a position sensor, it is desirable for the determined acceleration to be converted into a position of the object by integrating. If the sensor is formed as a velocity sensor, the determined acceleration can be converted into a velocity of the object by integrating.

The acceleration can be determined by detecting that current intensity supplied to the at least one coil which is desirable to keep the position of the auxiliary mass constant, to keep the position constant at least along the measuring axis, optionally to keep it stationary. If the sensor is formed as a position sensor, it is desirable for the determined acceleration to be converted into a position of the object by integrating. If the sensor is formed as a velocity sensor, the determined acceleration can be converted into a velocity of the object by integrating.

The lithography apparatus according to the disclosure having a plurality of objects has at least one sensor according to the disclosure, the at least one sensor being connected or connectable to at least one object. The object can be an optical element, for example a mirror or a lens element or a carrying structure, for example a sensor frame or a force frame. The lithography apparatus can also be an illumination device or a projection lens of a lithography apparatus.

The features and embodiments described in relation to the sensor are also applicable to the lithography apparatus comprising at least one sensor.

Further features, properties and aspects of the present disclosure are described in more detail below on the basis of embodiment variants and with reference to the appended figures. In this respect, all the features described above and below are desirable both individually and in any desired combination with one another. The embodiment variants described below are merely examples which, however, do not limit the subject matter of the disclosure. In the figures:

### BRIEF DESCRIPTION OF THE DRAWINGS

FIG. 1A shows a schematic illustration of a microlithographic projection exposure apparatus designed for operation in the EUV.

FIG. 1B shows a schematic illustration of a microlithographic projection exposure apparatus designed for operation in the DUV.

FIG. 2 shows a schematic illustration of a first exemplary embodiment of a vibration-correction unit.

FIG. 3 shows a schematic illustration of a second exemplary embodiment of a vibration-correction unit.

FIG. 4 shows a schematic illustration of a third exemplary embodiment of a vibration-correction unit.

FIG. 5 shows a schematic illustration of a sensor having a calibration unit.

### DETAILED DESCRIPTION

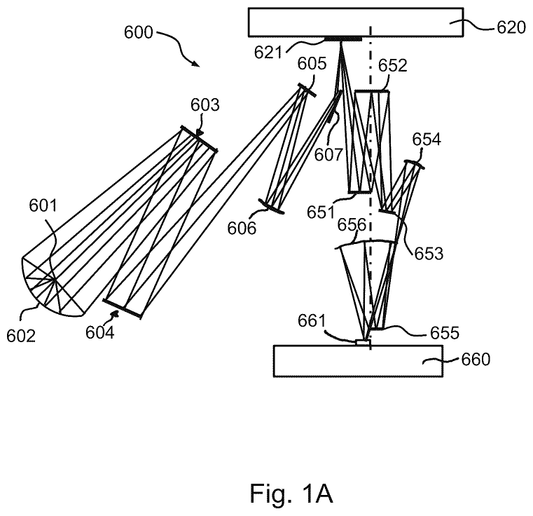

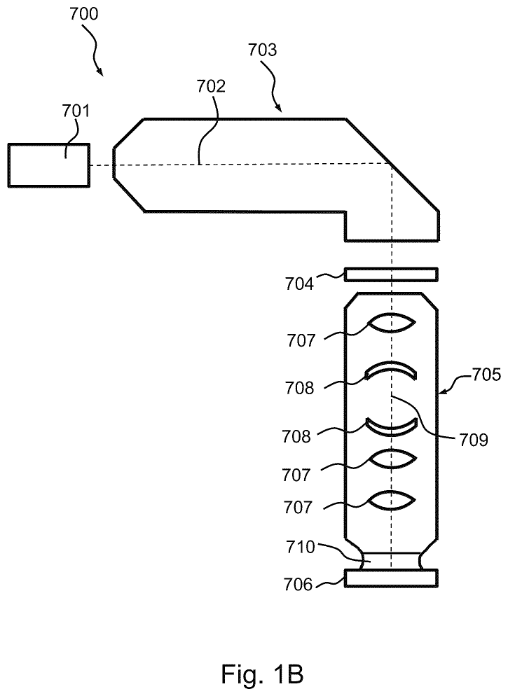

FIG. 1A shows a schematic illustration of an exemplary projection exposure apparatus 600 which is designed for operation in the EUV and in which the present disclosure can be realized.

According to FIG. 1A, an illumination device in a projection exposure apparatus 600 designed for EUV comprises a field facet mirror 603 and a pupil facet mirror 604. The light from a light source unit comprising a plasma light source 601 and a collector mirror 602 is directed to the field facet mirror 603. A first telescope mirror 605 and a second telescope mirror 606 are arranged downstream of the pupil facet mirror 604 in the light path. A deflection mirror 607 is arranged downstream in the light path and directs the radiation that is incident thereon onto an object field in the object plane of a projection lens comprising six mirrors 651-656. At the location of the object field, a reflective structure-bearing mask 621 is arranged on a mask stage 620 and with the aid of the projection lens is imaged into an image plane, in which a substrate 661 coated with a light-sensitive layer (photoresist) is situated on a wafer stage 660. The vibration-correction unit according to the disclosure can be used in the projection lens or in an illuminator of an EUV projection exposure apparatus.

The disclosure can likewise be used in a DUV apparatus, as illustrated in FIG. 1B. A DUV apparatus is set up in principle like the above-described EUV apparatus from FIG. 1A, wherein mirrors and lens elements can be used as optical elements in a DUV apparatus, and the light source of a DUV apparatus emits used radiation in a wavelength range of 100 nm to 300 nm.

The DUV lithography apparatus 700 illustrated in FIG. 1B comprises a DUV light source 701. For example, an ArF excimer laser that emits radiation 702 in the DUV range at for example 193 nm can be provided as the DUV light source 701. A beam shaping and illumination system 703 guides the DUV radiation 702 onto a photomask 704. The photomask 704 is designed as a transmissive optical element and can be arranged outside the systems 703. The photomask 704 comprises a structure that is imaged onto a wafer 706 or the like in a reduced fashion via the projection system 705. The projection system 705 comprises multiple lens elements 707 and/or mirrors 708 for imaging the photomask 704 onto the wafer 706. In this case, individual lens elements 707 and/or mirrors 708 of the projection system 705 can be arranged symmetrically with respect to the optical axis 709 of the projection system 705. It should be noted that the number of lens elements 707 and mirrors 708 of the DUV lithography apparatus 700 is not restricted to the number illustrated. A greater or lesser number of lens elements 707 and/or mirrors 708 can also be provided. In particular, the beam shaping and illumination system 703 of the DUV lithography apparatus 700 comprises multiple lens elements 707 and/or mirrors 708. Furthermore, the mirrors are generally curved on their front side for beam shaping purposes. An air gap 710 between the last lens element 707 and the wafer 706 can be replaced by a liquid medium having a refractive index of >1. The liquid medium can be high-purity water, for example. Such a setup is also referred to as immersion lithography and has an increased photolithographic resolution.

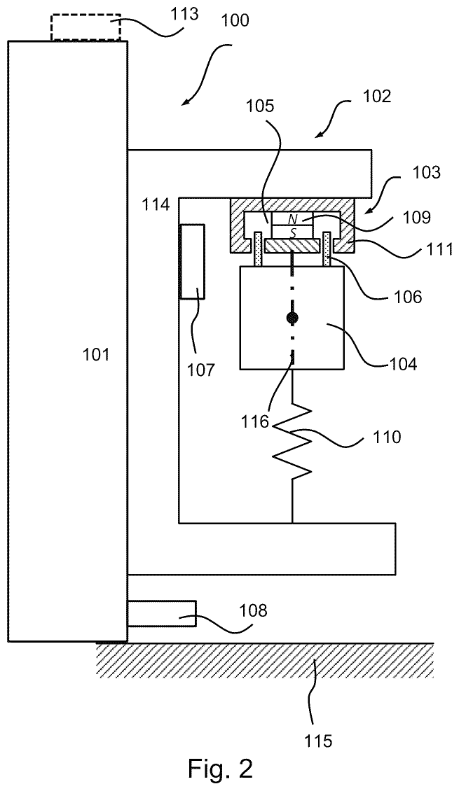

FIG. 2 shows a first exemplary embodiment of a vibration-correction unit 100 for an object 101 in a lithography apparatus having a sensor 102 connected to the object 101, the sensor comprising an electromagnetic actuator 103 and an auxiliary mass 104. The auxiliary mass 104 is connected to two spaced-apart coils 106 of the electromagnetic actuator 103, which project into a cavity 105 of the electromagnetic actuator 103. The auxiliary mass 104 is configured to perform a linear movement along a measuring axis 116, i.e. to guide the auxiliary mass 104 for a linear movement along the measuring axis 116. For this purpose, in the present case, the auxiliary mass 104 is suspended from a spring 110, wherein the auxiliary mass 104 is connected to the object 101 directly or indirectly via the spring 110. The object 101 can be connected at any point to the sensor 102 and thus to the spring 110. The electromagnetic actuator 103 is configured to generate a magnetic flux density B in the region of the coils 106. For this purpose, in the present case, the electromagnetic actuator 103 has a permanent magnet 109, but could alternatively also have a further actuator coil, not illustrated in more specific detail. Furthermore, a control unit 107 is present, which is configured to detect a measurement variable of the coils 106 relative to an absolute reference system 115. The control unit 107 is additionally configured to convert the detected measurement variable of the coil into an acceleration acting on the auxiliary mass 104 along the measuring axis 116. Furthermore, a compensation unit 108 is present, which is configured to exert on the object 101 a counterforce directed counter to the determined acceleration. The compensation unit 108 can comprise an actuator and be mounted at any point of the object 101.

The spring 110 of the auxiliary mass 104 is selected in such a way that the suspension frequency is between 0.1 Hz and 100 Hz, such as between 0.1 Hz and 50 Hz, for example between 1 Hz and 30 Hz. The spring 110 can be formed as a leaf spring or as a helical spring. Alternatively or additionally, it is also possible for the spring 110 to be formed as a permanent magnetic gravity compensator. Furthermore, more complex geometries can also be selected for the spring 110. For example, two magnetically identically oriented magnets can be arranged at a distance from one another along an axis which can be arranged parallel to the measuring axis 116. Provided in the central region of this axial magnetic arrangement is an outer circumferential magnetic ring, which at least partially encloses the inner magnets. The outer magnetic ring is magnetically oriented transversely with respect to the inner magnets, with the result that the inner pole of the outer magnet is adjacent to a like pole of the first inner magnet and to an opposite pole of the second inner magnet. This results in a magnetic force along the longitudinal axis between the inner and outer magnets which remains almost constant despite a relative displacement of the outer magnet with respect to the inner magnets in a wide range of displacement. This magnetic force can be used as a compensation force and thus decouples the auxiliary mass 104 from the object 101. Furthermore, it is also possible for the spring 110 to be formed as a combination of a leaf spring or a helical spring with a permanent magnetic gravity compensator. Alternatively, the spring 110 can also be formed as a plurality of helical springs and/or leaf springs that are coupled to one another. In particular, it is for the spring 110 to be formed as a gravity compensator in the direction of gravity.

FIG. 2 shows that the electromagnetic actuator 103 has a housing 111, which at least partially encloses the cavity 105 and is formed from a ferromagnetic material. This enables the other elements of the sensor 102 to be magnetically shielded vis-à-vis the magnetic field of the permanent magnet 109. Furthermore, the housing 111 leads to a concentration of the magnetic flux density in the region of the coil 106. The housing 111 has at least one opening through which the coils 106 project into the cavity 105. Furthermore, in the present case, the sensor 102 also has a sensor housing 114 enclosing the sensor 102 at least in some regions. The electromagnetic actuator 103 is mounted on the inner side of the sensor housing 114, as is the spring 110 of the auxiliary mass 104. The outer side of the sensor housing 114 can in turn be connected to the object 110.

In the exemplary embodiment according to FIG. 2, the measurement variable of the coil 106 detected by the control unit 107 is a voltage induced in the coils 106. The control unit 107 is additionally configured to determine a velocity of the auxiliary mass 104 on the basis of the detected induced voltage and to convert the velocity into an acceleration via the first derivative. Consequently, it is possible to indirectly determine the velocity by measuring the voltage induced in the coils 106 and to determine the acceleration of the auxiliary mass 104 by forming the first derivative of the velocity with respect to time. The acceleration of the auxiliary mass 104 is in turn proportional to the force acting on the object 101, so that the compensation unit 108 is configured to initiate a counterforce directed counter to the acceleration or force acting on the object 101, for example via a separate actuator. According to Faraday's law, the voltage induced in the coils 106 is proportional to the velocity and the magnetic flux density. The movement of the auxiliary mass 104 thus displaces the coils 106 within the cavity 105 of the electromagnetic actuator 103, thereby changing the magnetic field and inducing a voltage in the at least one coil 106, which is in turn a measure of the velocity at which the auxiliary mass 104 is moving. This enables the vibrations transmitted to the object to be determined more quickly and with an improved signal-to-noise ratio in comparison with the prior art.

If the sensor 102 is formed as a position sensor, the control unit is configured either to integrate the determined velocity or to integrate the determined acceleration twice in order to determine the position of the object 101.

The object 101 can be formed as a sensor frame, wherein the sensor frame has at least one position sensor for an optical element. In addition, an optical element can be suspended from the sensor frame. The sensor frame can be decoupled from the environment via a vibration isolation system, in particular via a spring or an air spring. Since, despite the vibration isolation system, in particular at the resonant frequency of the vibration isolation system, vibration of the sensor frame may nevertheless occur, the acceleration can be determined via the at least one sensor 102 according to the disclosure and a counterforce directed counter to the determined acceleration can be initiated via an actuator. The actuator can be the electromagnetic actuator 103 of the sensor 102 or else a further actuator. Alternatively, the vibration isolation system can additionally have a viscous damper in order to damp unwanted vibrations of the vibration isolation system. The sensor frame can be suspended from a force frame. Alternatively or additionally, the object 101 can be a force frame for an optical element of the lithography apparatus, in particular of the microlithographic projection exposure apparatus, wherein the force frame is connected to the optical element and at least one actuator connected to the optical element is mounted on the force frame for the purpose of adjusting or deforming the optical element. Alternatively, the object can also be an optical element of the lithography apparatus, in particular of the microlithographic projection exposure apparatus, for example a mirror or a lens element.

Furthermore, a further acceleration sensor 113 can additionally also be present, which is formed in a manner free of an electromagnetic actuator 103, for determining the acceleration of the object 101 along at least one axis. The further acceleration sensor can be formed as a piezoceramic sensor, but other types of acceleration sensors are also possible, in particular also MEMS sensors (Micro-Electro-Mechanical Sensors), such as MOEMS sensors (Micro-Opto-Electro-Mechanical Sensors). The movement of the object 101 can be detected both by the further acceleration sensor 113 and by the sensor 102 comprising the electromagnetic actuator 103.

Since the signal-to-noise ratio for the sensor 102 comprising the electromagnetic actuator 103 below approximately 100 Hz is better than the signal-to-noise ratio of a piezoceramic sensor and, conversely, the signal-to-noise ratio for the piezoceramic sensor above approximately 100 Hz is better than for the sensor 102 comprising the electromagnetic actuator 103, a low-pass filter is present for the purpose of attenuating the detected signal from the sensor 102 comprising the electromagnetic actuator 103 above a predefined cutoff frequency or a cutoff frequency range. A high-pass filter is assigned to the at least one further acceleration sensor 113 for the purpose of attenuating the detected signal below a predefined cutoff frequency or a cutoff frequency range, wherein the sum of the transfer function of the signals from the further acceleration sensor 113 and the sensor 102 comprising the electromagnetic actuator 103 is approximately 1. The cutoff frequency can be approximately in the range of 50 Hz to 500 Hz, such as between 70 Hz and 300 Hz, for example between 100 Hz and 200 Hz. In other words, optionally, the measurement data detected by the sensor 102 comprising the electromagnetic actuator 103 (distances or else distances differentiated once or twice) are used for smaller movements of the object, which (when Fourier-transformed) are smaller than a cutoff frequency or a cutoff frequency range, and the measurement data detected by the further acceleration sensor 113 are used for larger movements of the object 101, which are greater than a cutoff frequency or a cutoff frequency range. The larger movements which are detected by the sensor 102 comprising the electromagnetic actuator 103 and are greater than the cutoff frequency or the cutoff frequency range are in turn damped via the low-pass filter and the smaller movements which are detected by the further acceleration sensor 113 and are smaller than the cutoff frequency or the cutoff frequency range can be damped via the high-pass filter.

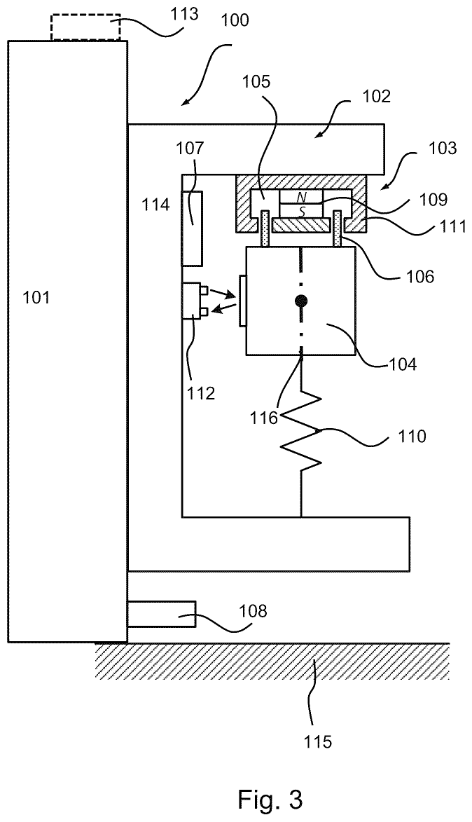

The exemplary embodiment according to FIG. 3 differs in that the measurement variable of the coil 106 is an electrical current intensity supplied to the at least one coil 106 of the electromagnetic actuator 103 and that a displacement sensor 112 is additionally present, which is configured to ascertain the position of the auxiliary mass 104. Furthermore, a control structure (not illustrated in more specific detail) is present, which can also be part of the control unit 107 and is formed as a microcontroller, for example. This control structure or the control loop is configured to supply electrical current to the coils 106 of the electromagnetic actuator 103 in such a way that the position of the auxiliary mass 104 detected by the displacement sensor 112 is constant at least along the measuring axis 116. The control structure keeps the position of the auxiliary mass 104 constant, in particular stationary or at least constant with respect to the at least one measuring axis 116. As a result of electrical current being supplied into the coils 106, the magnetic field of the electromagnetic actuator is changed, whereby the coils 106 are displaced in such a way that the movement of the auxiliary mass 104 caused by vibrations, for example, is compensated for by the supplied current intensity. The current intensity supplied into the coils 106 is proportional to the force acting on the auxiliary mass 104 and thus to the acceleration of the auxiliary mass 104, i.e. of the object 101.

If the sensor 102 is formed as a position sensor, the control unit 107 is configured to integrate the determined acceleration twice in order to determine the position of the object 101.

On the other hand, if the sensor 102 is formed as a velocity sensor, the control unit 107 is configured to convert the determined acceleration into a velocity of the object 101 by integration.

The displacement sensor 112 can be formed as an optical displacement sensor, for example an optical encoder or an interferometer. The optical encoder comprises, in an easily implementable form, a scale and a light source, and also a grating. Optical encoders typically include a beam splitter that splits the light emitted by the light source into two beams. The two beams are incident on the diffraction grating at two different positions and are diffracted there. The first beam is then projected onto a first mirror via a λ/4 plate and the second beam is projected onto a second mirror via a further λ/4 plate, where they are each reflected back onto the diffraction grating, diffracted there and directed back onto the beam splitter. The interference pattern indicated on the scale changes as a result of the movement of the object 101 and thus a change in distance between the object 101 and the auxiliary mass. Alternatively, the displacement sensor 112 can also be formed as a capacitive sensor. In the present case, the compensation unit 108 is formed as the electromagnetic actuator 103. However, an additional compensation unit can also be present as well.

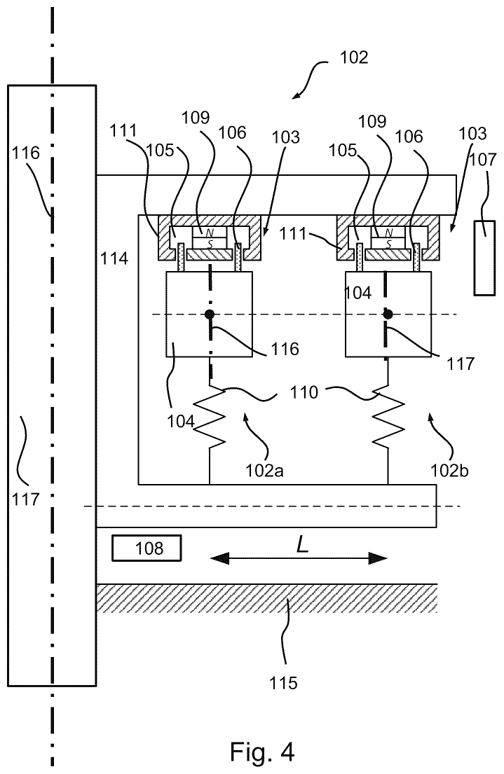

FIG. 4 shows a further exemplary embodiment, which differs in that two sensors 102, 102a, 102b according to the disclosure are arranged parallel to one another and spaced apart from one another with the length L. This arrangement makes it possible, using one of the sensors 102a, to ascertain the acceleration of the auxiliary mass 104, i.e. the acceleration acting on the object along a measuring axis 116. The other of the sensors 102b is used to ascertain the acceleration along an axis 117 differing from the measuring axis. This makes it possible to ascertain (calculate) the rotational movement, i.e. the acceleration of the auxiliary mass 104 along a rotation axis. Such an arrangement thus makes it possible to detect the acceleration of the object along two degrees of freedom (one translational degree of freedom and one rotational degree of freedom). Consequently, via three such arrangements according to FIG. 4, i.e. with a total of six sensors according to the disclosure, whose measuring axes 116 differ from one another, it is possible to determine the acceleration along all 6 rigid body degrees of freedom. The axes can be linearly independent, in particular perpendicular.

The method for operating a vibration-correction unit 100 according to the disclosure according to FIGS. 2 to 4 comprises at least the following steps:
Firstly, the measurement variable of the coil 106 is detected via the at least one sensor 102 comprising the electromagnetic actuator 103 and the auxiliary mass 104 along a measuring axis 116. The acceleration acting on the object 101 along the measuring axis 116 is determined on the basis of the detected measurement variable of the coil 106 and afterward a counterforce on the object 101 directed counter to the determined acceleration is generated for compensation or at least reduction of vibrations acting on the object 101.

In order also to be able to detect movements of the object above 100 Hz with a good signal-to-noise ratio over a wide frequency range, in the context of the method it is provided that the detected signals—i.e. movements—which are greater than a predefined or predefinable cutoff frequency or a cutoff frequency range of the displacement sensor 112 are attenuated via a low-pass filter, and if the detected signals—i.e. movements—which are smaller than a predefined or predefinable cutoff frequency or cutoff frequency range of a further acceleration sensor 113, which is formed in a manner free of an electromagnetic actuator 103, are attenuated via a high-pass filter, wherein the sum of the transfer function of the signals from the sensor 102 comprising the electromagnetic actuator 103 and the further acceleration sensor 102 is approximately 1. In other words, optionally, the signals detected by the sensor 102 comprising the electromagnetic actuator 103 are used for smaller movements of the object 101 below the cutoff frequency or below the cutoff frequency range, and the measurement signals detected by the further acceleration sensor 113 are used for larger movements of the object 101 above the cutoff frequency and above the cutoff frequency range. The larger movements which are detected by the sensor 102 comprising the electromagnetic actuator 103 and are greater than the cutoff frequency or the cutoff frequency range are damped via the low-pass filter and the smaller movements which are detected by the further acceleration sensor 113 and are smaller than the cutoff frequency or the cutoff frequency range can be damped via a high-pass filter.

In the method for operating the vibration-correction unit 100 according to FIG. 2 or FIG. 4, the measurement variable of the coil 106 is a voltage induced in the at least one coil 106 of the electromagnetic actuator 103. According to Faraday's law, the voltage induced in the at least one coil 106 is proportional to the velocity and the magnetic flux density B. The movement of the auxiliary mass 104 thus displaces the at least one coil 106 within the cavity 105 of the electromagnetic actuator 103, thereby changing the magnetic field and inducing a voltage in the at least one coil 106, which is in turn a measure of the velocity at which the auxiliary mass 104 is moving. The acceleration is determined by the voltage induced in the at least one coil 106 being converted into a velocity and the velocity being differentiated once with respect to time. In comparison with an acceleration sensor based on a displacement sensor, in order to determine the acceleration acting on the object, differentiation can be done once, as a result of which the acceleration can be determined more quickly.

In the method for operating the vibration-correction unit 100 according to FIG. 3 or FIG. 4, the measurement variable of the coil 106 is an electrical current intensity supplied to the at least one coil 106 of the electromagnetic actuator 103. The acceleration is determined by detecting that current intensity which is supplied to the at least one coil 106 in order to keep the position of the auxiliary mass 104 constant. The current intensity is in turn proportional to the acceleration of the auxiliary mass 104 and thus to the acceleration of the object 101.

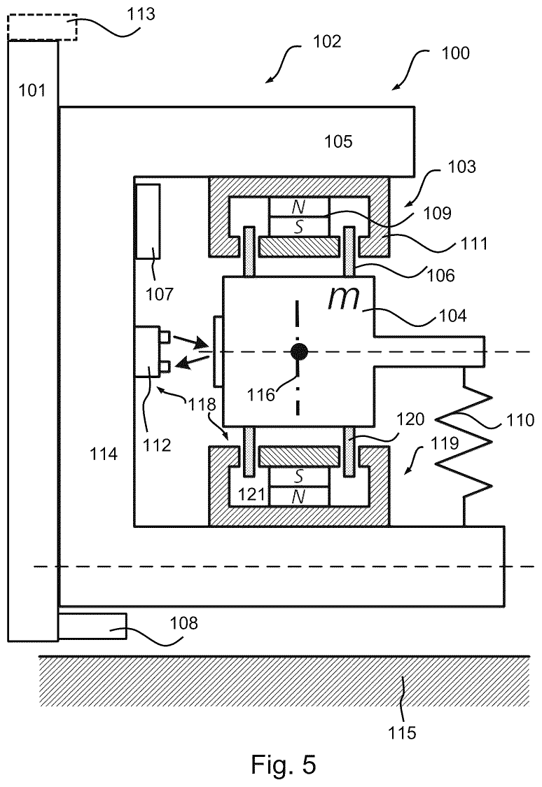

FIG. 5 shows one exemplary embodiment of the sensor 102 having a calibration unit 118. The calibration unit 118 is formed as a (further) electromagnetic element 119 arranged along the measuring axis 116. In the present case, the electromagnetic actuator 103 and the electromagnetic element 119 are arranged on opposite sides of the auxiliary mass 104. The calibration unit 118 comprises a calibration coil 120, which is connected to the auxiliary mass 104, and projects into a cavity 121 of the electromagnetic element 119, and also a displacement or velocity sensor 112 for detecting the movement or velocity of the auxiliary mass 104. Moreover, a voltmeter (not illustrated in more specific detail) is present, wherein the voltmeter of the sensor 102 can be used in this case, too. The electromagnetic element 119 can be formed as a permanent magnet, but can also be formed as a coil. The calibration unit 118 is configured to energize the calibration coil 120 with at least two different predefined or predefinable current intensities, in such a way that the calibration coil 120 causes a movement of the auxiliary mass 104. The calibration unit 120 can be additionally configured to detect the movement of the auxiliary mass 104 via the displacement sensor 112 and to convert it into a velocity, or to detect the velocity of the auxiliary mass directly via the velocity sensor (e.g. a Doppler interferometer). Furthermore, the calibration unit 118 is configured additionally to detect the voltage induced in the electromagnetic actuator 103 by the movement of the auxiliary mass 104. The detected values of the voltage induced in the coil of the electromagnetic actuator 103 at at least two different velocities are stored as calibration values, such as in a memory. This calibration value, i.e. the induced voltage divided by the velocity, corresponds to the magnetic flux density multiplied by the length of the coil 106 of the electromagnetic actuator 103. It goes without saying that the calibration can be carried out a number of times at predefined current intensities (velocities of the auxiliary mass). The calibration value or values detected in this way, i.e. the calibration unit 118, can be applied both to the measuring arrangement 100 in which the measurement variable is the induced voltage and to the measuring arrangement 100 in which the measurement variable is the supplied current intensity.

Alternatively, and not illustrated in more specific detail, the electromagnetic actuator 103 itself is part of the calibration unit. Consequently, no additional electromagnetic element is present. The calibration unit 118 then consequently comprises a voltmeter, a displacement or velocity sensor 112, a voltage source and a control and evaluation unit. The calibration unit 118 is configured to energize the coil 106 of the electromagnetic actuator 103 with different current intensities, in such a way that a movement of the auxiliary mass 104 is induced, and (at the same time) to determine the voltage induced in the electromagnetic actuator 103 by the movement of the auxiliary mass 104 via the voltmeter and the velocity detected via the displacement sensor 112 or the velocity sensor.

In a further exemplary embodiment (not illustrated in more specific detail), in which the electromagnetic actuator 103 itself is part of the calibration unit 118, the coil 106 of the electromagnetic actuator 103 is formed as a bifilar coil, in such a way that a first winding of the coil forms a measuring coil 106 of the sensor for vibration measurement and a second winding of the coil forms the calibration coil 120. The calibration unit 118 is in turn configured to energize the calibration coil 120 (i.e. the second winding of the coil) with different current intensities, in such a way that a movement of the auxiliary mass 104 is initiated, which is detected via the displacement sensor 112 and is converted into a velocity or is detected directly via a velocity sensor. Moreover, the calibration unit 118 is configured in turn to detect the voltage induced in the measuring coil 106 (i.e. the first winding of the coil) on account of the movement of the auxiliary mass 104 via a voltmeter and to assign the detected or determined velocities to the values of the induced voltage as calibration values and to store them in a memory. Furthermore, it goes without saying that the detected or determined (converted) velocity can be converted into an acceleration via forming the first derivative.

### LIST OF REFERENCE SIGNS

100 Sensor device
101 Object
102 Sensor
102a First sensor
102b Second sensor
103 Electromagnetic actuator
104 Auxiliary mass
105 Cavity
106 Coil
107 Control unit
108 Compensation unit
109 Permanent magnet
110 Spring
111 Housing
112 Displacement sensor
113 Further acceleration sensor
114 Sensor housing
115 Reference system
116 First measurement axis
117 Axis
118 Calibration unit
119 Electromagnetic element (of the calibration unit)
120 Calibration coil
121 Cavity (of the electromagnetic element)
600 Projection exposure apparatus
601 Plasma light source
602 Collector mirror
603 Field facet mirror
604 Pupil facet mirror
605 First telescope mirror
606 Second telescope mirror
607 Deflection mirror
620 Mask stage
621 Mask
651 Mirror (projection lens)
652 Mirror (projection lens)
653 Mirror (projection lens)
654 Mirror (projection lens)
655 Mirror (projection lens)
656 Mirror (projection lens)
660 Wafer stage
661 Coated substrate
700 DUV lithography apparatus
701 DUV light source
702 DUV radiation/beam path
703 Beam shaping and illumination system (DUV)
704 Photomask
705 Projection system
706 Wafer
707 Lens element
708 Mirror
709 Optical axis

1. A vibration-correction unit, comprising:
a first sensor connectable to an object, the first sensor comprising a first electromagnetic actuator and an auxiliary mass;
a first coil projecting in a cavity of the first electromagnetic actuator, the first coil connected to the auxiliary mass, the first coil extending into a cavity of the first electromagnetic actuator;
a spring configured to connect the object and the auxiliary mass;
a control unit; and
a compensation unit,
wherein:
the auxiliary mass is configured to move linearly along a measuring axis;
the first electromagnetic actuator is configured to generate a magnetic flux density in a region of the first coil;
the control unit is configured to detect a measurement variable of the first coil and to convert the measurement variable to an acceleration acting on the auxiliary mass along the measuring axis;
the compensation unit is configured to exert a counterforce on the object; and
the counterforce is counter to the acceleration acting on the auxiliary mass along the measuring axis.

2. The vibration-correction unit of claim 1, further comprising a second coil spaced apart from the first coil, wherein the second coil projects into the cavity of the first electromagnetic actuator, and the auxiliary mass is connected to the second coil.

3. The vibration-correction unit of claim 1, wherein the first electromagnetic actuator comprises a permanent magnet or an actuator coil, and the permanent magnet or actuator coil is configured to generate the magnetic flux density in the region of the first coil.

4. The vibration-correction unit of claim 1, wherein the first electromagnetic actuator comprises a housing at least partially enclosing the cavity of the first electromagnetic actuator, and the housing comprises a ferromagnetic material.

5. The vibration-correction unit of claim 1, wherein the measurement variable comprises a voltage induced in the first coil, and the control unit is configured to determine a velocity of the auxiliary mass based on the detected induced voltage and to convert the velocity into an acceleration via a first derivative of the velocity with respect to time.

6. The vibration-correction unit of claim 1, further comprising a second sensor comprising a second electromagnetic actuator and a second auxiliary mass, wherein the second sensor is configured to detect an acceleration acting on the object along an axis which is different from the measuring axis.

7. The vibration-correction unit of claim 6, further comprising an acceleration sensor, wherein the acceleration sensor is free of the first and second electromagnetic actuators, and the acceleration sensor is configured to detect the acceleration of the object along the axis which is different from the measuring axis.

8. The vibration-correction unit of claim 1, wherein the spring is configured to directly connect the object and the auxiliary mass.

9. The vibration-correction unit of claim 1, wherein the spring is configured to indirectly connect the object and the auxiliary mass

10. A system, comprising:
an object; and
the vibration-correction unit of claim 1,
wherein the object is connected to the first sensor.

11. The system of claim 10, further comprising an optical element, wherein the object comprises a sensor frame suspended from an optical element, and the sensor frame comprises a position sensor configured to sense a position of the optical element.

12. An apparatus, comprising:
a system, comprising:
an object; and
the vibration-correction unit of claim 1,
wherein the object is connected to the first sensor, and the apparatus comprises a lithography apparatus.

13. A vibration-correction unit, comprising:
a first sensor connectable to an object, the first sensor comprising a first electromagnetic actuator and an auxiliary mass;
a first coil projecting in a cavity of the first electromagnetic actuator, the first coil connected to the auxiliary mass, the first coil extending into a cavity of the first electromagnetic actuator;
a spring configured to connect the object and the auxiliary mass;
a control unit; and
a compensation unit,
wherein:
the auxiliary mass is configured to move linearly along a measuring axis;
the first electromagnetic actuator is configured to generate a magnetic flux density in a region of the first coil;
the control unit is configured to detect a measurement variable of the first coil and to convert the measurement variable to an acceleration acting on the auxiliary mass along the measuring axis; and
the compensation unit is configured to exert a counterforce on the object;
the counterforce is counter to the acceleration acting on the auxiliary mass along the measuring axis; and
the measurement variable comprises an electrical current intensity supplied to the first coil.

14. The vibration-correction unit of claim 12, further comprising a displacement sensor configured to ascertain a position of the auxiliary mass.

15. The vibration-correction unit of claim 13, further comprising a control structure configured to supply the electrical current to the first coil so that the position of the auxiliary mass ascertained by the displacement sensor is constant along the measuring axis.

16. The vibration-correction unit of claim 12, wherein the displacement sensor comprises an optical displacement sensor.

17. A system, comprising:
an object; and
the vibration-correction unit of claim 12,
wherein the object is connected to the first sensor, and the apparatus comprises a lithography apparatus.

18. The system of claim 17, further comprising an optical element, wherein the object comprises a sensor frame suspended from an optical element, and the sensor frame comprises a position sensor configured to sense a position of the optical element.

19. A method, comprising:
providing the vibration-correction unit of claim 1;
connecting the object to the first sensor;
detecting a measurement variable of the coil using the first sensor;
determining an acceleration acting on the object along the measuring axis based on the detected measurement variable of the first coil; and
generating the counterforce the acceleration on the object.

20.-23. (canceled)

24. A sensor, comprising:
an electromagnetic actuator;
an auxiliary mass;
a coil extending into a cavity of the electromagnetic actuator, the coil connected to the auxiliary mass;
a spring configured to connect an object to the auxiliary mass; and
a control unit,
wherein:
the auxiliary mass is configured to move linearly along a measuring axis; and
the electromagnetic actuator is configured to generate a magnetic flux density in a region of the coil.

25.-27. (canceled)
